(19) United States
(12) Patent Application Publication
(10) Pub. No.: US 2021/0064167 A1
(43) Pub. Date: Mar. 4, 2021

(54) Displays in Fabric-Covered Electronic Devices

(71) Applicant: Apple Inc., Cupertino, CA (US)

(72) Inventors: Yung-Yu Hsu, San Jose, CA (US); Kuan H. Lu, Santa Clara, CA (US); Mingjing Ha, Cupertino, CA (US); Paul S. Drzaic, Morgan Hill, CA (US); Yeguang Xue, Evanston, IL (US)

(21) Appl. No.: 16/555,953

(22) Filed: Aug. 29, 2019

(30) Foreign Application Priority Data
Aug. 26, 2019 (CN) 201910787970.3

(51) Int. Cl. G06F 3/041; G06F 1/16; G10L 15/22; H04R 1/02; H01L 27/32; H01L 51/00

(52) U.S. Cl. CPC G06F 3/0412; G06F 3/0416; G06F 1/1652; G10L 15/22; G06F 2203/04102; H01L 27/323; H01L 51/0097; G06F 2203/04103; H04R 1/026

(57) ABSTRACT

An electronic device such as a voice-controlled speaker device may have a cylindrical shape with upper and lower ends that have surface regions of compound curvature. The electronic device may have a display formed form an array of light-emitting devices such as light-emitting diodes. To provide the display with desired curvature (such as compound curvature), the display may be thermoformed. A flexible substrate for the display may be attached to a separate thermoplastic substrate. During a thermoforming process, the display may be heated such that the thermoplastic substrate softens into a pliable state. The display may then be molded into a desired shape. The display is then cooled to harden the thermoplastic substrate and secure the flexible substrate and light-emitting diodes in the desired shape. The thermoformed display may be stacked with additional functional layers such as a thermoformed touch-sensitive layer and/or a thermoformed lens layer.

This application claims the benefit of Chinese patent application No. 201910787970.3, filed Aug. 26, 2019, which is hereby incorporated by reference herein in its entirety.

### FIELD

This relates generally to electronic devices and, more particularly, to electronic devices with fabric.

### BACKGROUND

Electronic devices such as voice-controlled assistant devices may include fabric. As an example, the housing of a voice-controlled assistant device may be covered with a layer of fabric. Openings may be provided in the fabric to allow sound to be emitted from within the device.

It may be challenging to enhance the functionality of a voice-controlled assistant device. For example, it may be difficult to integrated light-emitting devices into a voice-controlled assistant device with a fabric layer. If care is not taken, the fabric may impart an undesired appearance to emitted light or the light-emitting devices may be visible from a limited range of angles, thereby preventing a light-emitting device from effectively conveying information to a user.

### SUMMARY

An electronic device such as a voice-controlled speaker device may have a housing characterized by a vertical axis. The device may have a cylindrical shape with upper and lower ends that have surface regions of compound curvature. The device may have an outermost layer formed by a fabric layer such as a knit fabric layer with diamond-shaped openings.

The electronic device may have a display formed form an array of light-emitting devices such as light-emitting diodes. To provide the display with desired curvature (such as compound curvature), the display may be thermoformed.

The display may include a flexible substrate such as a flexible mesh substrate with component support regions that are coupled by flexible segments. Light-emitting devices may be mounted on the component support regions of the flexible substrate. The flexible substrate may be attached to a separate thermoplastic substrate. During a thermoforming process, the display may be heated such that the thermoplastic substrate softens into a pliable state. The display may then be molded into a desired shape. The display is then cooled to harden the thermoplastic substrate and secure the flexible substrate and light-emitting diodes in the desired shape.

The thermoformed display may be stacked with additional thermoformed layers in the assembled electronic device. For example, a thermoformed touch-sensitive layer and/or a thermoformed lens layer may be formed over and conform to the thermoformed display. A fabric layer may also cover the display. In some cases, the fabric layer may serve as a light diffuser for the display.

Instead of attaching a flexible substrate for a display to a thermoplastic substrate for thermoforming, the display may instead have traces and light-emitting diodes formed directly on a thermoplastic substrate. The thermoplastic substrate may then be molded into a desired shape using thermoforming.

### BRIEF DESCRIPTION OF THE DRAWINGS

FIG. 1 is a perspective view of an illustrative voice-controlled electronic device having a housing covered with a fabric layer in accordance with an embodiment.

FIG. 2 is a cross-sectional side view of a portion of the device of FIG. 1 covered with illustrative layers of material in accordance with an embodiment.

FIG. 3 is a diagram of a portion of an illustrative layer of warp knit fabric in accordance with an embodiment.

FIG. 4 shows how a layer of fabric may have openings such as diamond-shaped openings in accordance with an embodiment.

FIG. 5 is a perspective view of an illustrative mesh layer formed from a flexible printed circuit having an array of openings patterned to form component mounting areas interconnected with serpentine paths in accordance with an embodiment.

FIG. 6 is a graph showing how the density of openings of a flexible substrate and/or the density of other characteristics of the substrate may be varied as a function of position in accordance with an embodiment.

FIG. 7 is a top view of a portion of an illustrative mesh substrate layer in accordance with an embodiment.

FIG. 8 is top view of an illustrative mesh flexible substrate layer with a ring-shaped footprint in accordance with an embodiment.

FIG. 9 is a cross-sectional side view of illustrative thermoformable display layers including a flexible substrate layer attached to a thermoplastic substrate in accordance with an embodiment.

FIG. 10 is a diagram showing an illustrative thermoforming process where a mold is biased into heated display layers in accordance with an embodiment.

FIG. 11 is a perspective view of illustrative display layers after being thermoformed in accordance with an embodiment.

FIG. 12 is an exploded view of an illustrative device with a thermoformed display and additional thermoformed functional layers in accordance with an embodiment.

FIG. 13 is a cross-sectional side view of an illustrative device with a thermoformed display covered by additional layers including a fabric layer in accordance with an embodiment.

FIG. 14 is a top view of an illustrative fabric layer showing how light-emitting devices may be mounted below intersection points that define diamond-shaped openings in accordance with an embodiment.

FIG. 15 is a top view of illustrative thermoformable display layers including a flexible substrate with component mounting areas arranged in concentric circles in accordance with an embodiment.

FIG. 16 is a perspective view of an illustrative display that is thermoformed to have a hemispherical upper surface in accordance with an embodiment.

FIG. 17 is a top view of illustrative thermoformable display layers including a flexible substrate with interconnects configured to buckle during stretching in accordance with an embodiment.

FIGS. 18A-18D are top views of illustrative thermoformable display layers including a flexible substrate with slits to promote stretching in accordance with an embodiment.

FIG. 19 is a flowchart of illustrative method steps for using thermoforming to form a display having desired curvature in accordance with an embodiment.

FIG. 20 is a top view of an illustrative thermoformable display with traces printed directly on a thermoplastic substrate in accordance with an embodiment.

FIG. 21 is a flowchart of illustrative method steps for using thermoforming of a thermoplastic substrate having printed traces such as in FIG. 20 to form a display having desired curvature in accordance with an embodiment.

### DETAILED DESCRIPTION

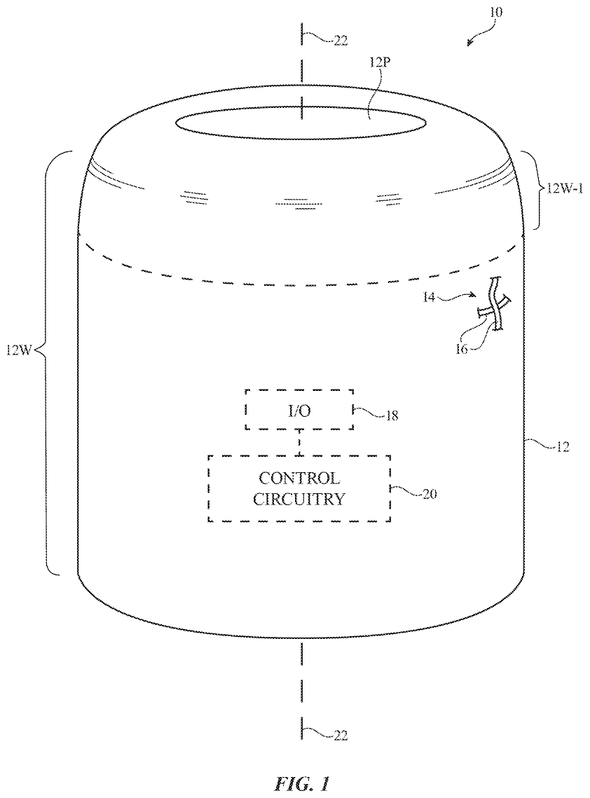

Items such as item 10 of FIG. 1 may include fabric. For example, fabric may be used in forming one or more covering layers for item 10 of FIG. 1. Item 10 may be an electronic device or an accessory for an electronic device such as a voice-controlled electronic device (sometimes referred to as a digital assistant or voice-controlled speaker), a laptop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which fabric-based item 10 is mounted in a kiosk, in an automobile, airplane, or other vehicle, other electronic equipment, or equipment that implements the functionality of two or more of these devices. If desired, item 10 may be a removable external case for electronic equipment, may be a strap, may be a wrist band or head band, may be a removable cover for a device, may be a case or bag that has straps or that has other structures to receive and carry electronic equipment and other items, may be a necklace or arm band, may be a wallet, sleeve, pocket, or other structure into which electronic equipment or other items may be inserted, may be part of a chair, sofa, or other seating (e.g., cushions or other seating structures), may be part of an item of clothing or other wearable item (e.g., a hat, belt, wrist band, headband, shirt, pants, shoes, etc.), or may be any other suitable fabric-based item. In the illustrative configuration of FIG. 1, item 10 is a voice-controlled electronic device such as a voice-controlled speaker with internet access. Other types of device may incorporate fabric, if desired.

As shown in FIG. 1, item 10 (sometimes referred to as device 10) may include a housing such as housing 12. Housing 12 may have a cylindrical shape with rounded upper and lower ends of the type shown in FIG. 1 or other suitable shape (e.g., a pyramidal shape, a conical shape, a box shape such as a rectangular box shape, a spherical shape, etc.). Housing 12 may include support structures formed from metal, polymer, ceramic, glass, wood, other materials, and/or combinations of these materials. The shape of housing 12 may be selected to form an enclosure suited to the type of item 10 for which the housing is being used. As an example, in scenarios in which item 10 is a voice-controlled electronic device, housing 12 may be cylindrical, pyramidal, box-shaped, conical, spherical, or other shapes suitable for enclosing one or more speakers, in configurations in which item 10 is a laptop computer, housing 12 may have upper and lower thin box-shaped portions that are joined with a hinge and that can respectively house a display and a keyboard, in configurations in which item 10 is a computer monitor containing an embedded computer, housing 12 may have a slender box shape with optionally curved rear housing walls that can hold a display and be mounted on a stand, in configurations in which item 10 is a tablet computer, cellular telephone, media player, or other handheld or portable electronic device, housing 12 may have a rectangular outline and a thin depth, in configurations in which item 10 is a smaller device such as a wristwatch device or a pendant device, housing 12 may have a thin profile and an outline that is rectangular, square, hexagonal, triangular, oval, or circular, in configurations in which item 10 is a headphone or earpiece device, housing 12 may have a shape configured to fit on or in a user's ear, in configurations in which item 10 is a pair of eyeglasses or other equipment worn on a user's head, housing 12 may have a head-mountable shape, in configurations in which item 10 is a jacket or other item of clothing (e.g., a hat, belt, wrist band, headband, shirt, pants, shoes, etc.), housing 12 may be formed from layers of fabric or other material configured to allow item 10 to be worn on a user's body, in configurations in which item 10 is a television, a computer display that does not contain an embedded computer, a gaming device, or a navigation device, housing 12 may have a rectangular outline, an outline with curved sides and/or straight sides, a box shape, a cylindrical shape, and/or other suitable shapes, in configurations in which item 10 is a kiosk, housing 12 can form a pedestal or other shape suitable for a kiosk, in configurations in which item 10 forms part of an automobile, airplane, or other vehicle, housing 12 may form a dashboard, console, door, window, seat, body panel, or other portion of the vehicle, in configurations in which item 10 is a removable external case for electronic equipment, housing 12 may have the shape of a sleeve or other structure with a recess for receiving the electronic equipment, in configurations in which item 10 is a strap, wrist band, necklace or headband, housing 12 may have a strip shape, in configurations in which item 10 forms a case, bag, or wallet, housing 12 may have surfaces that form the walls of the case and/or sides of the bag or wallet and/or that forms straps and/or other structures for the case or bag, and in configurations in which item 10 is part of furniture, housing 12 may be configured to form a part of a chair, sofa, or other seating (e.g., cushions or other seating structures). In the illustrative configuration of FIG. 1, housing 12 has a cylindrical shape suitable for an item such as a voice-controlled speaker with internet access. Housing 12 may have other shapes and may be incorporated into other items, if desired. The configuration of FIG. 1 is presented as an example.

Item 10 may include fabric 14. Fabric 14 may form all or part of a housing wall or other layer in an electronic device, may form the outermost layer of item 10, may form one or more inner covering layers, may form internal structures in an electronic device, or may form other fabric-based structures. Item 10 may be soft (e.g., item 10 may have a fabric surface that yields to a light touch), may have a rigid feel (e.g., the surface of item 10 may be formed from a stiff fabric), may be coarse, may be smooth, may have ribs or other patterned textures, and/or may be formed as part of a device that has portions formed from non-fabric structures of plastic, metal, glass, crystalline materials, ceramics, or other materials. In an illustrative configuration, some or all of the upper surface of housing 12 such as portion 12P may be formed from rigid polymer or other non-fabric structure and the sidewall surfaces of housing 12 may be covered with fabric 14. Portion 12P may include touch sensors, light-emitting devices (e.g., light-emitting diodes that backlight button icons and/or that produce other visual output for a user), and/or other input-output components. If desired, fabric 12 may cover some or all of portion 12P. Fabric 14 may serve as a cosmetic cover for item 10 that overlaps audio components (microphones and/or speakers) and is permeable to sound and and/or may be incorporated into other portions of item 10.

Fabric 14 may include intertwined strands of material such as strands 16. Fabric 14 may, for example, include warp knit fabric that is formed by warp knitting of strands 16 and/or may include woven fabric, fabric with braided strands of material, etc. Strands 16 may be single-filament strands (sometimes referred to as fibers or monofilaments) or may be strands of material formed by intertwining multiple monofilaments of material together (sometimes referred to as yarns).

Strands 16 may be formed from polymer, metal, glass, graphite, ceramic, natural materials such as cotton or bamboo, or other organic and/or inorganic materials and combinations of these materials. Conductive coatings such as metal coatings may be formed on non-conductive material. For example, plastic strands in fabric 14 may be coated with metal to make them conductive. Reflective coatings such as metal coatings may be applied to make strands reflective. Strands formed from white polymer (e.g., light-scattering particles in polymer) and/or that are coated with white polymer may help reflect light in some configurations. If desired, strands may be formed from bare metal wires or metal wire intertwined with insulating monofilaments (as examples). Bare metal strands and strands of polymer covered with conductive coatings may be provided with insulating polymer jackets. In some configuration, strands 16 may include optical fibers (e.g., lossy optical fibers with surface roughening or other features that allow the strands to guide light while emitting portion of the guided light outwardly). Optical waveguide strands (e.g., lossy optical fibers formed from glass, transparent polymer, etc.) can be provided with light from light sources such as light-emitting diodes to display information (e.g., desired patterns of light). In some cases, it may be desirable for lossy fiber to appear dark or colored in reflection when illuminated by external light, so that the lossy fiber may match the appearance of other fibers. In these cases, the lossy fiber can include regions that are colored on the outside of the fiber but only leak light slightly or not at all and other regions that emit light due to roughen of the fiber surface or localized adjustments to the cladding of the fiber in that region (e.g., localized cladding thinning).

Items such as item 10 may, if desired, include control circuitry 20. Control circuitry 20 may include microprocessors, microcontrollers, application-specific integrated-circuits, digital signal processors, baseband processors, and/or other controllers and may include storage such as random-access memory, read-only memory, solid state drives, and/or other storage and processing circuitry.

Control circuitry 20 may gather information from sensors and other circuitry in input-output devices 18 and may use input-output devices 18 to supply output. Input-output devices 18 may, for example, include audio devices such as microphones and speakers. Microphones can gather audio input (e.g., sound that passes through fabric 14 such as voice commands for controlling the operation of item 10). Speakers can produce audio output (e.g., sound that passes through fabric 14). Sensors in input-output devices 18 may include touch sensors, force sensors, capacitive sensors, optical sensors, proximity sensors, strain gauges, temperature sensors, moisture sensors, gas sensors pressure sensors, magnetic sensors, position and orientation sensors (e.g., accelerometers, gyroscopes, and/or compasses), and/or other sensors. Light-emitting diodes, displays, and other visual output devices may be used in supply visual output to a user. As an example, visual output devices may be used to form illuminated buttons, displays that display images, visual feedback areas that display still and/or moving patterns of light to indicate to a user that a command has been received and/or is being processed by control circuitry 20, etc. Buttons, joysticks, haptic output components, and/or other input-output components may be provided in input-output devices 18 to gather input from a user and to provide a user with output. Wireless circuitry in circuitry 20 (e.g., wireless local area network circuitry, cellular telephone circuitry, etc.) may be used to support wireless communications with external equipment.

Light-emitting devices (e.g., lasers or light-emitting diodes) may be arranged in an array of pixels to form a display or other light-based output device. As an example, light-emitting devices may be formed under one or more covering layers (e.g., fabric) on item 10. The light-emitting devices may be formed just in a ring-shaped upper region 12W-1 that runs around the upper edge of item 10 and/or may be formed on one or more other portions of item 10 (e.g., on some or all of exterior sidewall surface 12W-2). In general, the surfaces of item 10 such as the surface of housing portion 12P and the sidewalls of item 10 may be provided with any suitable input-output devices 18. Sidewall locations in item 10 (e.g., the upper sidewall area associated with region 12W-1 and/or the sidewall areas associated with region 12W-2) may, as an example, be provided with light-emitting devices (e.g., to form a pixel array for displaying images that include text, still image content, moving image content, icons, etc.), may be provided with sensors (e.g., an array of force sensors, touch sensors, proximity sensors, gesture sensors, accelerometers for gathering touch/tap input, domes switches or other pressure-activated switches, etc.), and/or other input-output devices 18. These sidewall locations in item 10 may wrap partly or entirely around the periphery of item 10 (e.g., light-emitting devices, sensors, and/or other components may be provided on sidewall areas that wrap around a longitudinal axis of item 10 such as vertical axis 22 and extend along some or all of the circumference of item 10). Some or all of the surfaces of item 10 may be covered with one or more layers of material including fabric and/or other layer(s) such as polymer layers, metal layers, etc. If desired, light-emitting devices in item 10 may emit light in the infrared, which is invisible to the user, but can be detected by external sensors and devices to support light-based communication between item 10 and external devices. Item 10 may also include infrared light-detectors to support infrared light-based communications.

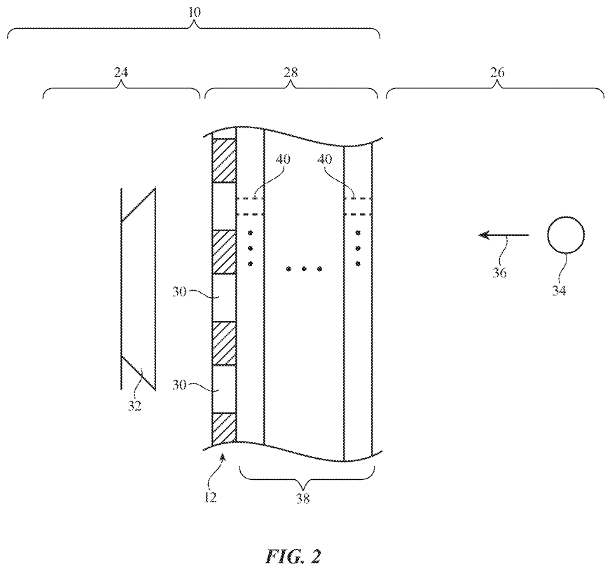

A cross-sectional side view of a portion of item 10 is shown in FIG. 2. In the example of FIG. 2, item 10 includes internal components such as one or more speakers 32 in interior 24 of item 10. Wall structures 28 (e.g., sidewall structures) may separate interior 24 from exterior 26. A user of item 10 (e.g., user 34) may view the exterior of item 10 in direction 36 and may listen to sound that has been emitted from speaker 32 and that has passed through wall structures 28.

Wall structures 28 may include a housing formed from one or more rigid support structures (e.g., a metal housing wall, a plastic housing wall, a housing wall formed from other material and/or combinations of these materials). As shown in FIG. 2, for example, wall structures 28 may include housing 12 (e.g., a housing wall such as a housing sidewall and/or other housing wall structures). Housing 12 may have acoustic openings 30 to allow sound to pass through housing 12. Openings 30 may be circular, square, diamond-shaped, or may have other suitable shapes. The lateral dimensions of openings 30 may be at least 0.1 mm, at least 1 mm, at least 5 mm, at least 15 mm, less than 30 mm, less than 60 mm, or other suitable size.

Covering layers 38 may overlap the exterior surface of housing 12. Covering layers 38 may have openings 40. The outermost of covering layers 38 may, as an example, serve as a cosmetic layer (e.g., a layer that provides item 10 with a desired color, texture, etc.). Inner covering layers (e.g., layers 38 that are interposed between the outermost layer and housing 12) may include adhesive layers for attaching layers together, cushioning layers (e.g., layers of foam and/or fabric to provide layers 38 with a cushiony feel), component layers (e.g., substrates with electrodes, metal traces forming interconnects, integrated circuits, light-emitting components, sensors such as touch sensor arrays or force sensors, and/or other circuitry), light-modifying layers (e.g., diffuser layers, reflective layers, layers for hiding internal components from view, etc.), component-hiding layers or other layers such as acoustically transparent layers that block light and/or that block moisture, dust, and other environmental contaminants, and/or other covering layer structures. Layers 38 may, if desired, include coating layers (e.g., one or more layers of liquid polymer containing light-scattering particles, dye, pigment, and/or other materials that can be applied in liquid form and cured to form solid coatings, coating layers of metal or other materials deposited using physical vapor deposition, chemical vapor deposition, and/or electrochemical deposition, and/or other coatings).

One or more of layers 38 may include fabric 14. Fabric 14 may, for example, overlap some or all of the exterior of housing 12 (e.g., fabric 14 may overlap at least region 12W-2 of FIG. 1). Fabric 14 may also be used in forming straps, covers, wearable items, and/or other structures for item 10.

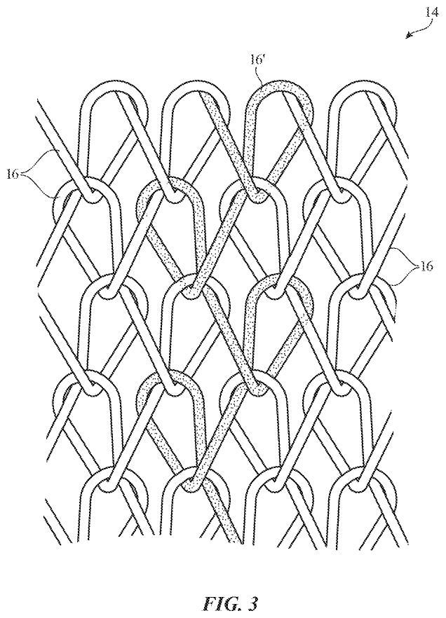

A warp knitting machine or other equipment (e.g., weaving equipment, braiding equipment, weft knitting equipment, etc.) may be used in intertwining strands 16 to form fabric 14. In general, fabric 14 may be any suitable type of fabric (e.g., woven fabric, knit fabric, braided fabric, etc.). A layer of illustrative warp knit fabric 14 is shown in FIG. 3. An illustrative strand 16′ among strands 16 has been highlighted to show the zig-zag path taken by each strand in fabric 14.

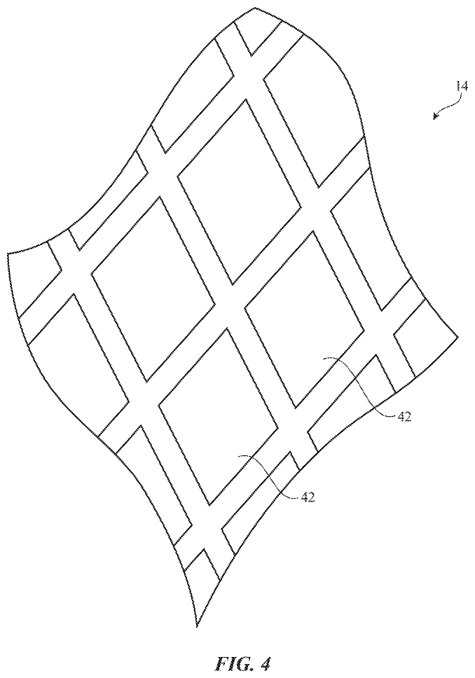

During the process of forming fabric 14 (e.g., during knitting), a warp knitting machine or other fabric fabrication equipment that is forming fabric 14 may, if desired, direct positioners in the equipment to incorporate openings into fabric 14. As an example, the equipment may be directed to form knit fabric or other fabric that includes diamond-shaped openings or openings of other suitable shapes, as illustrated by openings 42 in warp knit fabric 14 of FIG. 4. In configurations in which fabric 14 forms one of layers 38, openings 42 may serve as openings 40 of FIG. 2.

One or more of layers 38 of FIG. 2 may include a fabric layer or a polymer layer (e.g., a perforated polymer sheet) or other substrate layer with openings (e.g., openings that are sufficiently large to allow acoustic signals to pass). A polymer layer may, as an example, have a coating for reflecting and/or blocking light (e.g., one of layers 38 may be a polymer substrate and another of layers 38 may be a coating on the polymer substrate).

It may be desirable to form a display (e.g., an array of light-emitting components) in device 10. In some configurations, light from a display may be emitted through portion 12P of housing 12. However, in some situations a user may view device 10 from the side. In these scenarios, it may be difficult for the user to see portion 12P on the upper surface of the device. To allow for viewing of the display at more viewing angles, a display may be formed in housing region 12W-1 (e.g., in addition to or instead of in portion 12P). With this type of configuration, the display light will be visible from both the sides of the device and the top of the device.

It may be difficult to form displays for device 10 that conform to the curvature of housing region 12W-1. Because the housing is curved along multiple axes in region 12W-1 (e.g., has compound curvature), a display layer may need to be stretchable in order to conform to the shape of the curved surface. A stretchable display layer may include light-emitting diodes mounted to a flexible substrate. The flexible substrate may have openings in order to allow the flexible substrate to stretch. In one example, the flexible substrate may have islands (e.g., rigid islands) that are connected by serpentine, stretchable interconnects. In another example, the flexible substrate may have interconnects that buckle to allow stretching of the flexible substrate. The flexible substrate may have slits that allow stretching of the substrate.

Regardless of the type of stretchable flexible substrate used, it may be desirable to secure the flexible substrate once the flexible substrate has stretched to have desired curvature (e.g., compound curvature). This may be achieved using one or more thermoplastic substrates. A thermoplastic substrate is capable of being heated to a pliable forming temperature. The flexible substrate with an array of light-emitting diodes may be mounted to the thermoplastic substrate. The thermoplastic substrate may be heated to the pliable forming temperature and then molded to have a desired shape (e.g., a shape matching the curvature of region 12W-1). The flexible substrate that is attached to the thermoplastic substrate will also have the desired shape and curvature. The thermoplastic substrate is then cooled (solidified) while in the desired shape. After cooling, the thermoplastic substrate will maintain the desired shape and secure the flexible substrate and light-emitting diodes in the desired shape. This process (e.g., of heating, molding, and cooling) may be referred to as thermoforming.

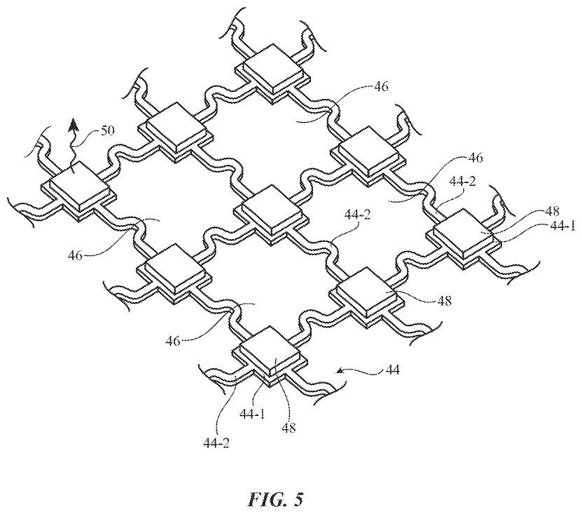

A perspective view of an illustrative flexible substrate layer with openings and serpentine interconnects that may be used to form a display for device 10 is shown in FIG. 5. Metal traces and/or electrical components may be incorporated into the substrate. Flexible polymer substrates with metal traces (e.g., flexible layers of polyimide or other sheets of flexible polymer with metal traces) may sometimes be referred to as flexible printed circuits. Flexible printed circuits may be used to form input-output components such as a display for device 10.

Layer 44 of FIG. 5 may be a flexible printed circuit substrate or other substrate layer with an array of openings forming a mesh shape (sometimes referred to as a mesh layer, mesh, or flexible mesh). One or more layers such as mesh layer 44 of FIG. 5 may be included in layers 38 of FIG. 2. For example, one or more layers such as layer 44 of FIG. 5 may be interposed in layers 38 between an outer layer of fabric 14 (see, e.g., FIG. 4) and housing 12.

As shown in FIG. 5, layer 44 may have an array of openings 46. Layer 44 may have regions 44-1 (sometimes referred to as islands, island regions, component mounting areas, or component support regions) to which components 48 are soldered or otherwise mounted (see, e.g., the circuitry forming input-output devices 18 and/or control circuitry 20 of FIG. 1). Components 48 may be, for example, packaged or unpackaged semiconductor dies for forming integrated circuits, sensors, light-emitting devices, and/or other circuitry. With one illustrative configuration, components 48 are semiconductor dies forming one or more light-emitting devices such as light-emitting diodes or lasers (e.g., vertical cavity surface emitting lasers or other lasers) that emit light 50 (e.g., light 50 that exits layer 44 vertically, parallel to the surface normal of layer 44). Components 48 may also include sensors (e.g., capacitive touch sensors, etc.) and/or other input-output devices 18. If desired, a component 48 may include multiple semiconductor dies and/or other electrical components in a common package. For example, red, green, and blue light-emitting diodes and an optional control circuit and/or sensor circuits such as capacitive touch sensors can be placed in a common package. Electrostatic discharge protection circuitry can be incorporated into components 48 and/or the circuitry coupled to components 48 to help protected light-emitting diodes, touch sensors and other sensitive circuitry from electrical damage during electrostatic discharge events (e.g., when a user is touching the surface of item 10).

To enhance flexibility in flexible printed circuit 44, regions 44-1 may be interconnected by elongated portions of layer 44 such as segments 44-2. Segments 44-2 may extend from one of regions 44-1 to another and may extend between openings 46. Segments 44-2 may be straight, may be curved, or may have both straight and curved portions. In the illustrative configuration of FIG. 5, segments 44-2 have serpentine shapes to help enhance the flexibility and stretchability of layer 44 without damaging layer 44 or components 48. Other mesh-shaped support structures may be used, if desired (e.g., mesh substrates with circular openings, triangular openings, hexagonal openings, mesh patterns with a combination of circular and square openings, meshes with non-regular patterns of openings, etc.).

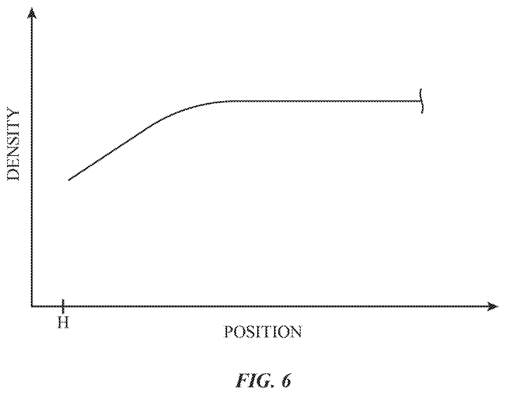

Item 10 may have curved outer surfaces (e.g., surfaces with compound curvature as shown by the curved surfaces of item 10 of FIG. 1). Flexible substrates such as substrate 44 of FIG. 5 and other flexible layers 38 may have an array of openings 46 that is configured to help the layer(s) have curved surfaces of the desired curvature. If desired, the density of openings 46 (e.g., the number, size, and/or shape of openings 46 per unit area) may be varied as a function of lateral distance across the surface of substrate 44 when substrate 44 is in a planar configuration. As shown in FIG. 6, for example, the density of openings 46 may be decreased at the portions of layer 44 at the upper end of item 10 (e.g., near where vertical dimension Z is equal to height H of item 10). For example, openings 46 may be larger (and components 48 spaced farther apart) on the portions of layer 44 that are to be coupled to the upper end of item 10 (e.g., in region 12W-1). When layer 44 is subsequently molded to be curved (e.g., attached to the outer surface of housing 12), the lower-density portions of layer 44 will increase in density (because the spacing between portions of layer 44 will decrease as layer 44 laterally contracts when it conforms to the surfaces of housing 12 at the ends of item 10). As a result, following assembly of item 10 by attaching layer 44 to housing 12, components 48 that are located at the curved end of item 10 will have an identical or nearly identical pitch (component-to-component spacing) as those components 48 that are located in the middle of item 10 (e.g., midway up the height of item 10).

The example of FIG. 6 is merely illustrative. In general, the flexible substrate may be designed to account for stretching that will distort the flexible substrate. The flexible substrate may initially be pre-distorted such that the stretching places the components in desired locations.

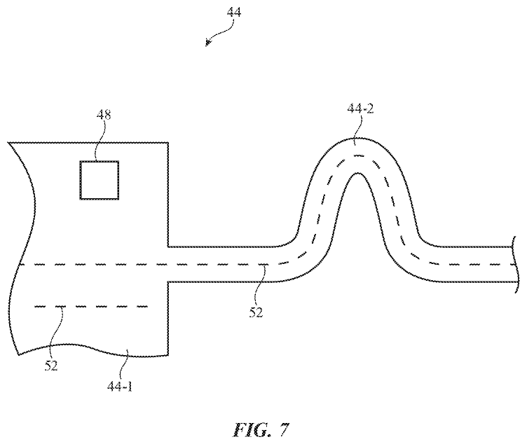

FIG. 7 is a top view of layer 44 showing how structures such as metal traces 52 and components 48 may be formed on layer 44. Metal traces 52 and components 48 may, for example, be formed on component support regions 44-1. In some configurations, portions of metal traces 52 (and, if desired, circuit components) may extend onto segments 44-2. Metal traces 52 may be used in forming antennas, capacitive sensing electrodes for a capacitive touch sensor and/or capacitive proximity sensor, or electrodes for making other measurements such as force measurements, moisture measurements, temperature measurements, etc. Metal traces 52 can route signals between components 48 and can be used to interconnect components 48 with control circuitry 20. Components 48 may include light-emitting devices, sensor circuitry, haptic output components and other input-output circuitry (see, e.g., devices 18 of FIG. 1), and/or other circuitry in item 10.

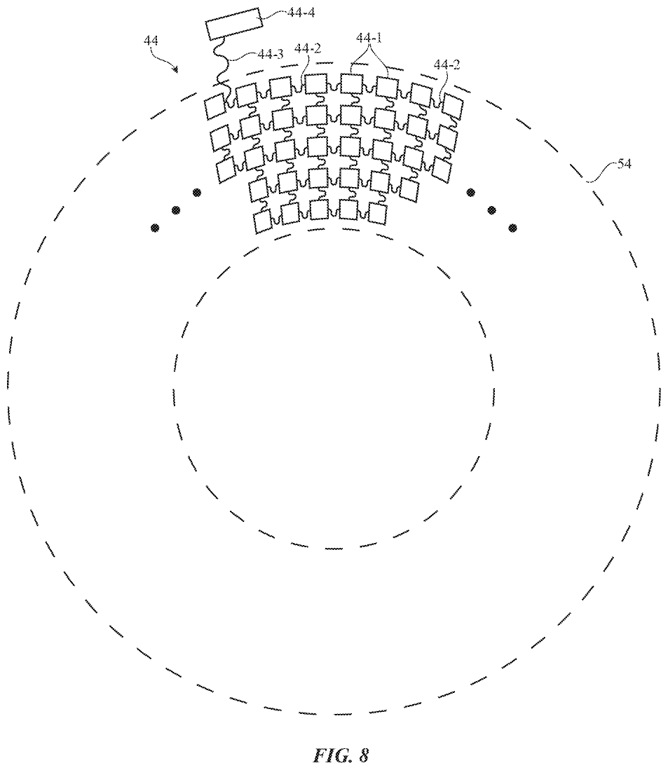

FIG. 8 is a top view of an illustrative flexible substrate layer 44 showing an illustrative footprint for the flexible substrate layer. As shown in FIG. 8, flexible substrate layer 44 includes island regions 44-1 that are interconnected by elongated segments 44-2 (as previously shown in FIG. 5). It should be understood that each island region 44-1 in FIG. 8 may include one or more light-emitting devices (e.g., light-emitting diodes) and may optionally include additional input-output components.

As shown, flexible substrate layer 44 may be formed in a ring-shaped footprint 54 (sometimes referred to as annular footprint, donut-shaped footprint, etc.). The ring-shaped footprint may be shaped to overlap portions of device 10 such as region 12W-1. This example is merely illustrative. In general, flexible substrate layer 44 may have any desired footprint and may cover any desired portions of device 10.

The flexible substrate of FIG. 8 may also include an additional interconnect portion 44-3 that is used to couple the light-emitting diodes to a connecting portion 44-4 of the flexible substrate. Connecting portion 44-4 of the flexible substrate may be connected to driving circuitry (e.g., control circuitry 20 in FIG. 1) that is used to control the light-emitting diodes. Interconnect portion 44-3 may have one or more curved portions that allows the interconnect portion to be stretched if desired. Interconnect portion 44-3 may be described as having a serpentine shape. In FIG. 8, only one interconnect portion 44-3 and connecting portion 44-4 are shown. This example is merely illustrative. If desired, there may be multiple connections between the light-emitting diodes and additional control circuitry using respective interconnect portions 44-3 and connecting portions 44-4 of flexible substrate 44. The interconnect portions 44-3 and connecting portions 44-4 may be evenly distributed around the perimeter of the ring-shaped footprint in one example.

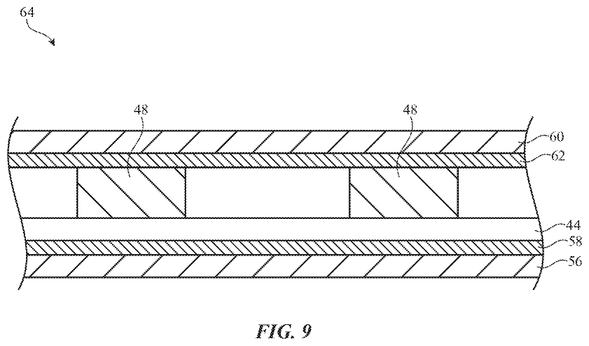

To secure the flexible substrate layer with a desired curvature, the flexible substrate layer may be attached to a thermoplastic substrate. FIG. 9 is a cross-sectional side view of an illustrative thermoformable display 64 with a flexible substrate attached to a thermoplastic substrate. As shown in FIG. 9, flexible substrate layer 44 may be attached to thermoplastic substrate 56 with adhesive layer 58. Thermoplastic substrate 56 (sometimes referred to as thermoformable substrate 56) may be formed from a material that is capable of being heated to a pliable forming temperature. The thermoplastic substrate may be able to be stretched and molded when heated. When cooled (e.g., in a solid state), the thermoplastic substrate may maintain its shape without bending or stretching. Any desired thermoplastic material may be used to form thermoplastic substrate 56. The thermoformable substrate may be formed from a polymer (thermoplastic) such as polyvinyl chloride (PVC), polyethylene terephthalate (PET), acrylonitrile butadiene styrene (ABS), high-impact polystyrene (HIPS), high-density polyethylene (HDPE), a non-polymer material such as glass, or any other desired material. The thermoformable substrate may have a thickness of less than 1 millimeter, less than 3 millimeters, less than 5 millimeters, less than 0.5 millimeters, less than 0.4 millimeters, less than 0.3 millimeters, less than 0.1 millimeters, greater than 0.1 millimeters, between 0.3 and 0.5 millimeters, or any other desired thickness.

Thermoplastic substrate 56 may be transparent or may be opaque. Adhesive layer 58 that attaches flexible substrate 44 to thermoplastic substrate 56 may be formed from an optically clear adhesive (OCA), a pressure sensitive adhesive (PSA), or any other type of adhesive. Adhesive layer 58 may be transparent or may be opaque.

Light-emitting diodes 48 are mounted on flexible substrate 44. As shown in FIG. 9, an optional additional thermoplastic substrate may be formed over the light-emitting diodes. Thermoplastic substrate 60 may be attached to light-emitting diodes 48 using adhesive layer 62. Thermoplastic substrate 60 may form a protective layer over the light-emitting diodes (e.g., the thermoplastic substrate 60 may conform to the light-emitting diode array and protect the light-emitting diodes from damage when incorporated into device 10). Because thermoplastic substrate 60 and adhesive layer 62 cover the light-emitting diodes, thermoplastic substrate 60 and adhesive layer 62 may be formed form a transparent material. Adhesive layer 62 that attaches light-emitting diodes 62 to thermoplastic substrate 60 may be formed from an optically clear adhesive (OCA), a pressure sensitive adhesive (PSA), or any other type of adhesive. An additional flexible substrate layer may optionally be interposed between light-emitting diodes 48 and adhesive layer 62.

The stack-up of FIG. 9 (with light-emitting diodes mounted to a flexible substrate and one or more thermoplastic substrates) may sometimes be referred to as thermoformable display 64, thermoformable display layers 64, display 64, thermoformed display 64, etc. The thermoformable display may include any desired number of light-emitting diodes (e.g., more than twenty, more than fifty, more than one hundred, more than two hundred, more than five hundred, more than one thousand, more than five thousand, more than ten thousand, less than ten thousand, less than five thousand, less than one thousand, less than five hundred, less than two hundred, less than one hundred, etc.).

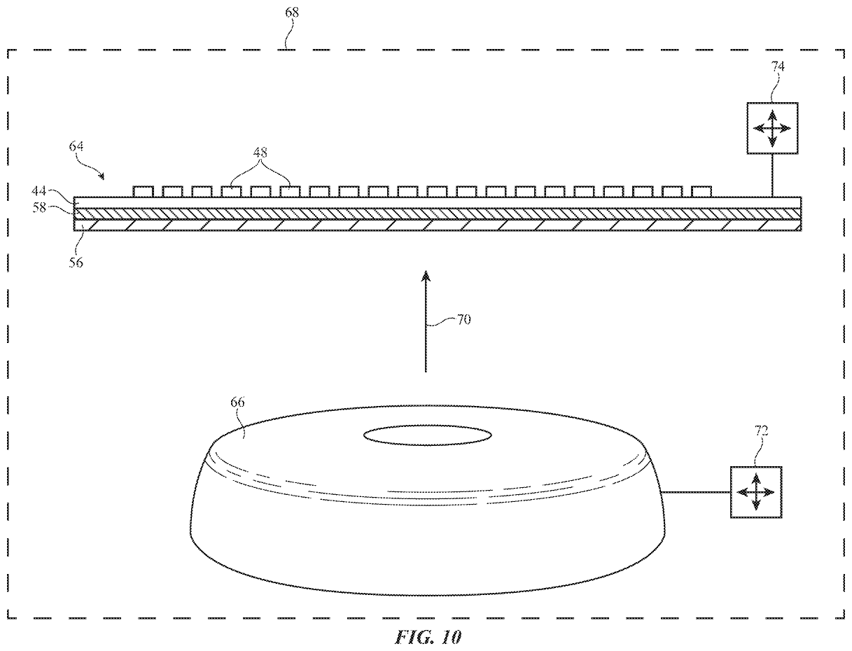

FIG. 10 is a diagram showing how the thermoformable display of FIG. 9 may be molded into a desired shape. As shown in FIG. 10, thermoformable display layers 64 may be positioned above a mold such as mold 66. Mold 66 may have the desired final shape intended for the thermoformable display (e.g., with compound curvature). Mold 66 may be formed from any desired material (e.g., plastic, metal, wood, etc.).

During the thermoforming process, display layers 64 may be heated to soften thermoplastic substrate 56. In the example of FIG. 10, thermoformable display layers 64 and mold 66 are formed in a temperature-controlled chamber 68 that is heated to a desired temperature. This example is merely illustrative, and there are many other ways to heat display layers 64 for the thermoforming process.

While thermoplastic substrate 56 is at the desired temperature, mold 66 may be moved in direction 70 (e.g., by computer-controlled positioner 72) to contact display layers 64. When mold 66 contacts display layers 64, the display layers may conform to the shape of mold 66. Because thermoplastic substrate 56 is heated the thermoplastic substrate may stretch over mold 66 to match the curvature of mold 66. Similarly, flexible substrate 44 is also stretchable and will conform to the curvature of mold 66 (with thermoplastic substrate 56 intervening between mold 66 and flexible substrate 44). Once display layers 64 conform to the surface of mold 66, the display layers may be cooled (e.g., by reducing the temperature in chamber 68, by removing the display layers and mold from the chamber, etc.). Once cooled, thermoplastic substrate 56 will solidify, thus securing flexible substrate 44 and the corresponding light-emitting diodes in the shape of mold 66.

In FIG. 10, display layers 64 are depicted without optional additional thermoplastic substrate 60 and adhesive layer 62 of FIG. 9. However, these layers may of course be included in display layers 64 during the thermoforming process if desired.

During the thermoforming process, the thermoplastic substrates may be heated past their glass transition temperature (Tg) but below their melting temperature. Above the glass transition temperature, the thermoplastic substrate will transition from a hard and rigid material to a soft and pliable material capable of conforming to mold 66. If heated past the melting temperature, the polymer would be liquified and would not be able to conform to the shape of mold 66. The material for the thermoplastic substrates may be selected to have a glass transition temperature higher than ambient temperatures expected during normal operations of the assembled device. This prevents the thermoplastic substrate from undesirably softening/reshaping once the finished product is being used by a consumer.

In practice, the thermoplastic substrates may be heated to a temperature greater than 50° C., greater than 75° C., greater than 100° C., greater than 150° C., greater than 200° C., less than 50° C., less than 75° C., less than 100° C., less than 150° C., less than 200° C., between 50° C. and 100° C., between 75° C. and 150° C., or any other desired temperature during thermoforming.

In the example of FIG. 10, mold 66 is biased towards display layers 64 in direction 70 by a computer-controlled positioner 72 coupled to the mold. This example is merely illustrative. In addition or instead, display layers 64 may be biased towards mold 66 (e.g., in a direction opposite direction 70) by a computer-controlled positioner 74 that is coupled to the display layers. Additional steps may be taken to ensure that display layers 64 conform to the surfaces of mold 66. For example, a vacuum may be drawn to pull the display layers in contact with mold 66. Air may be blown at the display layers to bias the display layers in contact with the surface of mold 66. Equipment such as mold 66, computer-controlled positioner 72, computer-controlled positioner 74, and chamber 68 may sometimes be referred to as thermoforming equipment.

FIG. 10 shows an example of a positive mold. A positive mold has a convex shape whereas a negative mold has a concave shape. Either type of mold may be used during thermoforming of display 64. When a negative mold is used, the negative mold may have a cavity with the desired curvature of display layers 64 (e.g., the inverse of mold 66 in FIG. 10). The display layers may be heated past the glass transition temperature of the thermoplastic substrate, biased to conform to the curved surfaces of the cavity, then cooled to secure the display in a shape that matches the curvature of the negative mold.

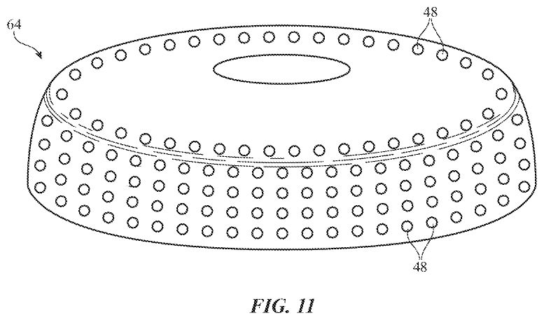

FIG. 11 is a perspective view of an illustrative display 64 after the thermoforming process is complete. As shown, thermoformed display 64 has a shape with curvature that matches the curvature of mold 66 in FIG. 10. Light-emitting diodes 48 have a ring-shaped footprint around the curved edges of the display. The curvature of display 64 may match the curvature of region 12W-1 of FIG. 1, for example. Because the thermoplastic substrate of display 64 has solidified, the shape of the display will not change and the positions of the light-emitting diodes 48 will remain constant.

In the example of FIG. 11, the thermoplastic substrate has a continuous upper surface. in other words, the thermoplastic substrate is formed even in portions of the display that are not covered by light-emitting diodes 48. This example is merely illustrative. If desired, the thermoplastic substrate may be omitted in portions that are not covered by flexible substrate 44 and light-emitting diodes 48 (e.g., the thermoplastic substrate may have a ring-shaped footprint similar to the light-emitting diode array).

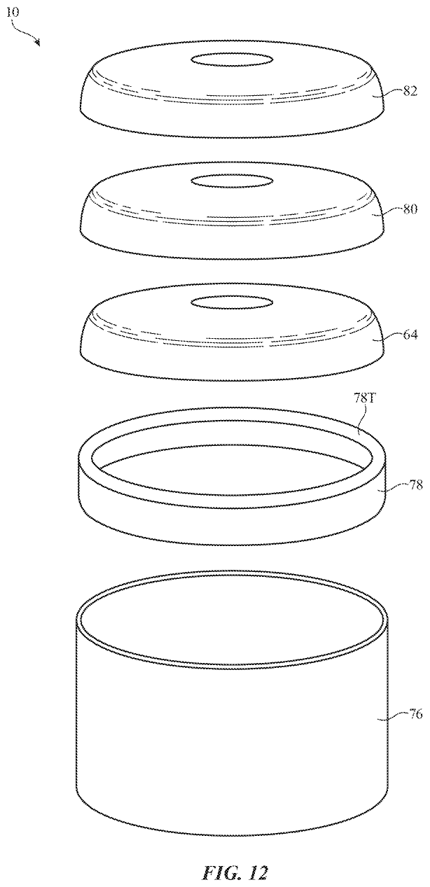

FIG. 12 is an exploded view of an illustrative device 10 that includes a thermoformed display 64. As shown in FIG. 12, device 10 may include a housing structure such as enclosure 76. Enclosure 76 may be a hollow cylinder formed from plastic, metal, or another desired material. Enclosure 76 may house components for device 10 such as control circuitry 20 and/or input-output devices 18 in FIG. 1. Enclosure 76 may sometimes be referred to as housing structure 76.

Enclosure 76 may receive a functional member 78 that supports input-output components (e.g., proximity sensors or other desired sensors). Functional member 78 may also serve as a support structure for display 64. In one illustrative example, functional member 78 may have a top surface 78T with a groove that receives the bottom edges of thermoformed display 64.

Additional functional layers that are also optionally thermoformed may be nested with thermoformed display 64. In FIG. 12, thermoformed touch sensor layer 80 may conform to the shape of underlying display 64. In this way, display 64 is made touch-sensitive. An additional layer such as lens layer 82 may be formed over touch sensor layer 80. Lens layer 82 (sometimes referred to as top cap 82 or diffuser layer 82) may be used to diffuse light emitted by the light-emitting diode array of display 64.

Touch sensor layer 80 and top cap 82 may be formed using a thermoforming process similar to as shown in FIG. 10. Both touch sensor layer 80 and top cap 82 may be transparent. Alternatively, one or both of touch sensor layer 80 and top cap 82 may have both transparent portions and opaque portions.

In the example of FIG. 12, thermoformable display 64 is supported by support structure 78 of device 10. There is no additional housing structure that conforms to an inner surface of display layer 64. This example is merely illustrative, and an additional housing structure (or part of enclosure 76) may be included in device 10 that conforms to an inner surface of display layer 64. In either case, display layer 64 may sometimes be considered a housing structure (e.g., housing 12 is formed by enclosure 76, display layer 64, and support structure 78). Alternatively, display layer 64 may be considered to be coupled to (or housed within) a housing 12 formed by enclosure 76 and support structure 78.

In FIG. 12, display layer 64 is conformally stacked with touch sensor layer 80 and top cap 82. In other words, display layer 64 is nested within touch sensor layer 80 and touch sensor layer 80 is in turn nested within top cap 82. The outer surface of display layer 64 may conform to and be in direct contact with the inner surface of touch sensor layer 80. The outer surface of touch sensor layer 80 may conform to and be in direct contact with the inner surface of top cap 82. Device 10 may include other thermoformed functional layers that are included in the nested stack-up. Similarly, one or both of touch sensor layer 80 and top cap 82 may be omitted from device 10 if desired. In general, device 10 may include any desired number of functional layers that conform to the shape of display layer 64. Each functional layer may optionally be thermoformed to have the same shape as display layer 64.

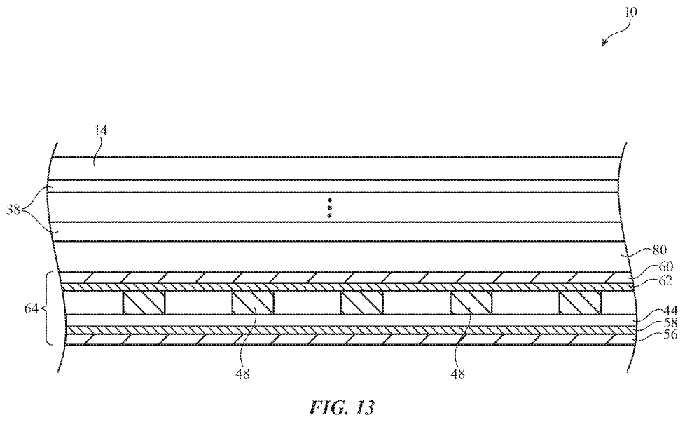

Additional layers may be used to cover thermoformed display 64 if desired. For example, a fabric layer may cover thermoformed display 64. FIG. 13 is a cross-sectional side view of an illustrative device with a thermoformed display covered by fabric. In this example, the arrangement of thermoformed display 64 is the same as previously shown in FIG. 9, with a thermoplastic substrate 56 attached to flexible substrate 44 by adhesive layer 58, light-emitting diodes 48 mounted to flexible substrate 44, and thermoplastic layer 60 attached to the light-emitting diodes 48 by adhesive layer 62. Additionally, a touch-sensitive layer 80 is formed over display 64. Touch-sensitive layer 80 may include transparent electrode structures (e.g., formed from indium tin oxide) that are used to detect touch from a user. The transparent electrode structures may be formed on a transparent thermoplastic substrate in one configuration.

Additional covering layers 38 may be formed over touch-sensitive layer 80. Covering layers 38 may include cosmetic layers (e.g., a layer that provides item 10 with a desired color, texture, etc.), adhesive layers for attaching layers together, may include cushioning layers (e.g., layers of foam and/or fabric to provide layers 38 with a cushiony feel), component layers (e.g., substrates with electrodes, metal traces forming interconnects, integrated circuits, sensors such as touch sensor arrays or force sensors, and/or other circuitry), light-modifying layers (e.g., diffuser layers, reflective layers, layers for hiding internal components from view, etc.), component-hiding layers or other layers such as acoustically transparent layers that block light and/or that block moisture, dust, and other environmental contaminants, and/or other covering layer structures. Layers 38 may, if desired, include coating layers (e.g., one or more layers of liquid polymer containing light-scattering particles, dye, pigment, and/or other materials that can be applied in liquid form and cured to form solid coatings, coating layers of metal or other materials deposited using physical vapor deposition, chemical vapor deposition, and/or electrochemical deposition, and/or other coatings). Touch-sensitive layer 80 and display 64 may also be considered to be covering layers 38.

The outermost layer of device 10 may be fabric layer 14. Fabric 14 may serve as a cosmetic cover for device 10. Fabric 14 may be permeable to sound. Fabric may cover any or all of the surfaces of device 10 (e.g., the side surfaces and upper surfaces), with a portion of the fabric overlapping the light-emitting diodes of the thermoformed display. In some configurations such as the arrangement of FIG. 13, fabric 14 may serve as a diffuser layer for light from light-emitting diodes 48. In other words, a portion of fabric layer 14 is designed to cover and diffuse light that is emitted from light-emitting diodes 48 in thermoformable display 64. In the example of FIG. 13, lens layer 82 (from FIG. 12) is omitted. However, lens layer 82 may also be included over touch sensor layer 80 between the touch sensor layer and fabric layer 14.

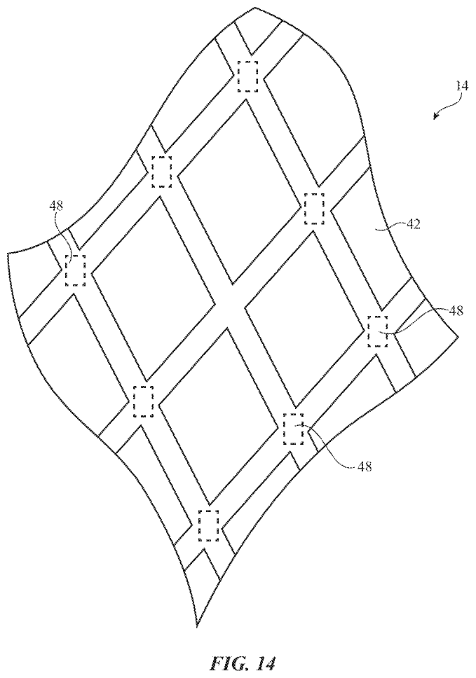

In configurations where fabric layer 14 serves as a light diffuser for display 64, the light-emitting diodes may be positioned relative to the fabric to achieve desired diffusion characteristics. For example, as previously mentioned in connection with FIG. 4, fabric 14 may have diamond-shaped openings or openings of other suitable shapes. In FIG. 14, fabric 14 has diamond-shaped openings 42. To increase the diffusion of light from the light-emitting diodes by the fabric, the light-emitting diodes may be aligned with intersection points of the fabric (e.g., vertices of the diamond-shaped openings). FIG. 14 shows how each light-emitting diode 48 may be positioned under a respective intersection of fabric 14.

Examples have been described where a device 10 includes a thermoformed display 64 having a ring-shaped footprint and formed along curved surfaces on an upper edge of device 10 (e.g., in region 12W-1 in FIG. 1). These examples are merely illustrative. In general, a thermoformed display may have any desired shape depending on the design of the particular device 10. In one additional example, device 10 may have a hemispherical upper surface. Additionally, instead of the light-emitting diode array having a ring-shaped footprint the light-emitting diode array may completely cover the upper surface of the device.

FIG. 15 is a top view of illustrative display layers 64 that may be used to conform to a hemispherical upper surface of device 10. As shown in FIG. 15, display layers 64 include a flexible substrate 44 that is similar to the flexible substrate of FIG. 5. Similar to as in FIG. 5, flexible substrate 44 in FIG. 15 includes regions 44-1 (sometimes referred to as islands, island regions, component mounting areas, or component support regions) to which components 48 are soldered or otherwise mounted (see, e.g., the circuitry forming input-output devices 18 and/or control circuitry 20 of FIG. 1). Components 48 may be, for example, packaged or unpackaged semiconductor dies for forming integrated circuits, sensors, light-emitting devices, and/or other circuitry. Components 48 may also include sensors (e.g., capacitive touch sensors, etc.) and/or other input-output devices 18. If desired, a component 48 may include multiple semiconductor dies and/or other electrical components in a common package. For example, red, green, and blue light-emitting diodes and an optional control circuit and/or sensor circuits such as capacitive touch sensors can be placed in a common package. To enhance flexibility in flexible printed circuit 44, regions 44-1 may be interconnected by elongated portions of layer 44 such as segments 44-2. Segments 44-2 may extend from one of regions 44-1 to another and may extend between openings 46. Segments 44-2 may be straight, may be curved, or may have both straight and curved portions. In the illustrative configuration of FIG. 15, segments 44-2 have serpentine shapes to help enhance the flexibility and stretchability of layer 44 without damaging layer 44 or components 48.

In FIG. 5, the flexible substrate has a grid-like arrangement such that the light-emitting diodes are arranged in evenly spaced rows and columns. In FIG. 15, the flexible substrate is instead arranged to have regions 44-1 (and correspondingly, light-emitting diodes 48) distributed in concentric circles extending away from a center of the flexible substrate. As shown in FIG. 15, a light emitting diode 48C may be formed at the center of the flexible substrate. The serpentine interconnects 44-2 and island regions 44-1 are then arranged such that a circle of seven light-emitting diodes is formed around the center light-emitting diode 48C. A circle of twelve light-emitting diodes is then formed that also has light-emitting diode 48C as a center. This pattern may continue for any desired size of flexible substrate, with progressively larger concentric circles of light-emitting diodes formed around a center light-emitting diode.

Similar to as in FIG. 8, flexible substrate 44 may include an interconnect 44-3 and connecting portion 44-4 for coupling the flexible substrate to control circuitry. In FIG. 15, only one interconnect portion 44-3 and connecting portion 44-4 are shown. This example is merely illustrative. If desired, there may be multiple connections between the light-emitting diodes and additional control circuitry using respective interconnect portions 44-3 and connecting portions 44-4 of flexible substrate 44. The interconnect portions 44-3 and connecting portions 44-4 may be evenly distributed around the perimeter of the flexible substrate in one example.

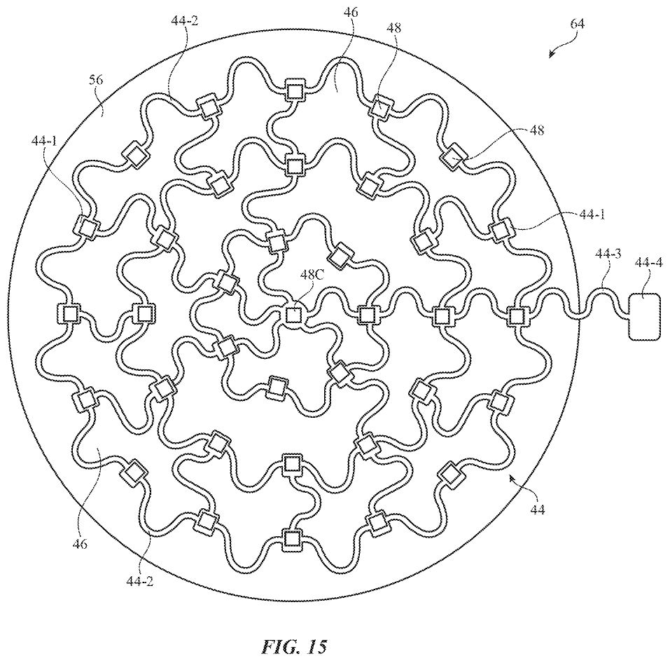

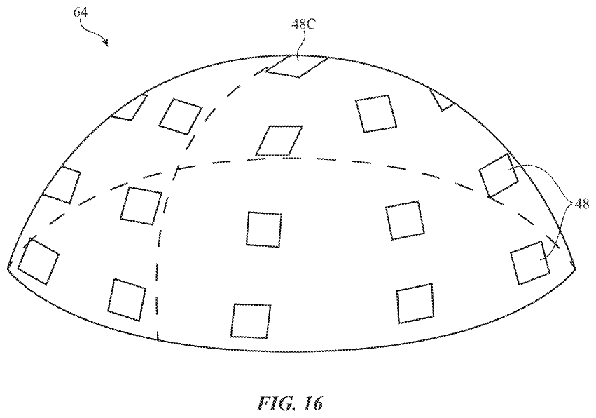

The flexible substrate with light-emitting diodes 48 is formed on a thermoplastic substrate 56. Therefore, display layers 64 may undergo a thermoforming process to mold the display layers into a desired shape (e.g., to conform to a hemispherical upper surface). FIG. 16 is a perspective view of display layers 64 after the display has been thermoformed to have a hemispherical upper surface.

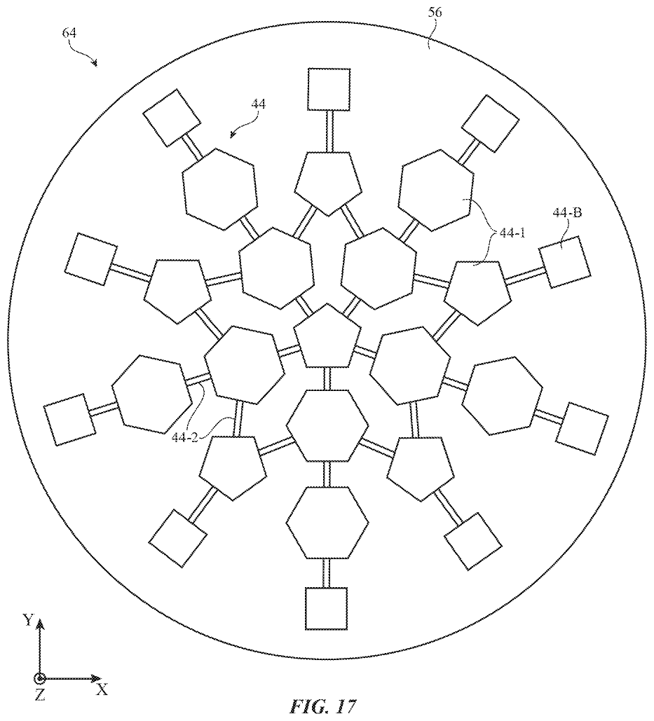

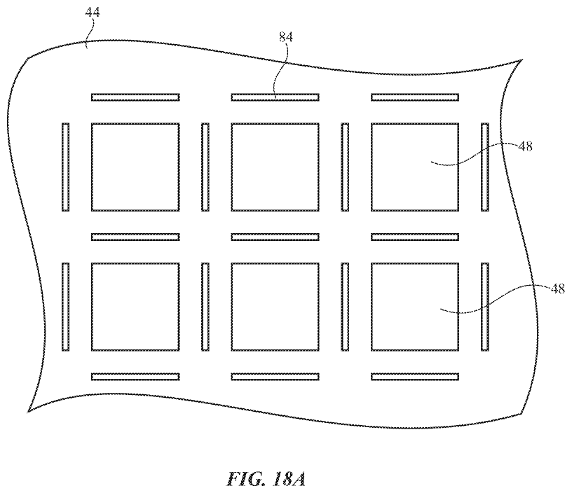

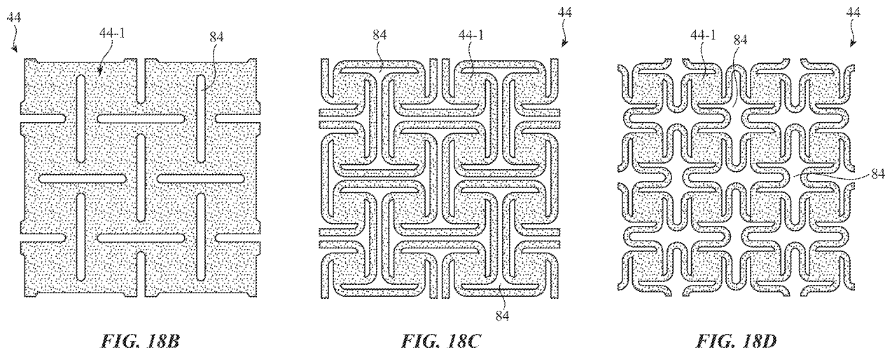

FIGS. 17 and 18 are top views of additional flexible substrates that may be used to form thermoformed displays in device 10. In FIG. 17, flexible substrate 44 includes regions 44-1 connected by elongated interconnect regions 44-2. The regions 44-1 may be rigid and may each support attached components such as light-emitting diodes 48. Instead of having serpentine interconnects between each region 44-1 (as in FIG. 5), the flexible substrate of FIG. 17 may have interconnects 44-2 that are configured to bend out of the XY-plane when the flexible substrate is stretched. Flexible substrate 44 may have bond pad regions 44-B that are attached to the underlying thermoplastic substrate 56. However, the portions of flexible substrate 44 aside from bond pad regions 44-B may not be attached to the thermoplastic substrate. Therefore, when the flexible substrate is stretched during thermoforming, interconnects 44-2 may be free to bend out of the plane (e.g., the interconnects 44-2 may not be coplanar with portions 44-1 of the flexible substrate. When the bond pads 44-B are secured in place (e.g., when the thermoplastic substrate is solidified after thermoforming), the positions of the light-emitting diodes may also be secured.

In FIG. 18A, flexible substrate 44 has slits 84 formed around each light-emitting diode 48. Each light-emitting diode may be surrounded by four elongated slits 84, with each elongated slit extending along a respective longitudinal axis. The four elongated slits may approximate the shape of a square that surrounds the light-emitting diode (and the light-emitting diode mounting region of the flexible substrate). During thermoforming, the slits may allow the flexible substrate to stretch and conform to the shape of the thermoforming mold. The arrangement of FIG. 18A may allow for a higher density of light-emitting diodes in the thermoformed display than the mesh arrangements of FIGS. 5 and 15.

The illustrative pattern of slits in FIG. 18A is merely illustrative. Other patterns of slits may be used, as shown in FIGS. 18B-18D. In FIG. 18B, component mounting regions 44-1 may be surrounded by slits 84. Unlike in FIG. 18A, each slit in FIG. 18B extends adjacent to two component mounting regions 44-1 (instead of just one as in FIG. 18A). Each slit in FIG. 18B may extend orthogonally between the centers of two adjacent slits. In FIG. 18C, flexible substrate 44 may have I-shaped slits 84 that are formed between component mounting regions 44-1. Each I-shaped slit 84 may have first and second portions that extend along first and second parallel axes and a third portion that extends orthogonal to the first and second portions between the centers of the first and second portions. Each component mounting region may be surrounded by respective portions of four different I-shaped slits. In FIG. 18D, flexible substrate 44 may have a number of slits 84 that each include six portions extending from a common central area. Each component mounting region 44-1 may be surrounded by a respective portion of four different slits 84. The examples of FIGS. 18A-18D are merely illustrative and other slit patterns may be used if desired.

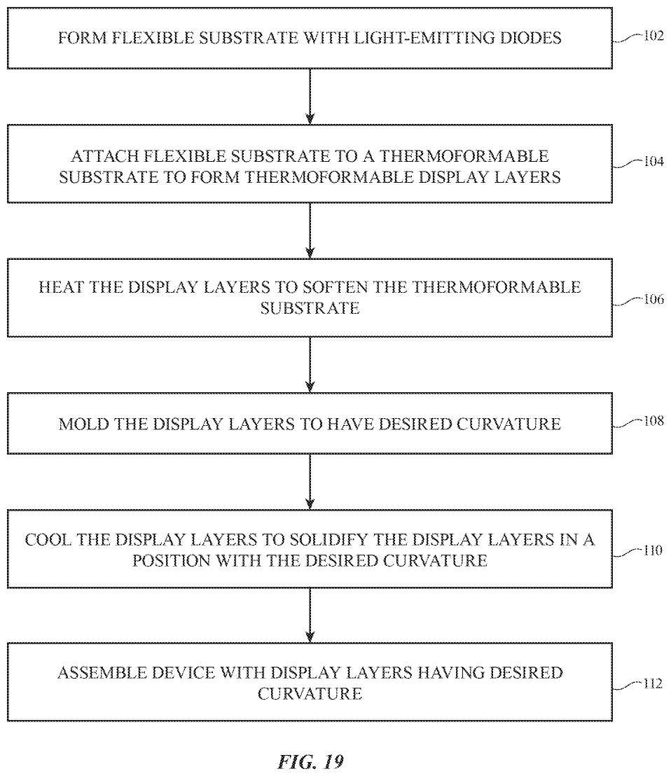

FIG. 19 is a flowchart showing illustrative method steps for forming a display with curved surfaces. First, at step 102, a flexible substrate may be formed. Light-emitting diodes may be mounted to the flexible substrate. The light-emitting diodes may be soldered to component mounting areas of the flexible substrate, for example. The flexible substrate may have openings that allow the flexible substrate to be stretched. The flexible substrate may have serpentine interconnects between the component mounting areas that are arranged in a grid (as in FIG. 5). In another example, the flexible substrate may have serpentine interconnects between component mounting areas that are arranged in concentric circles (as in FIG. 15). In yet another example, shown in FIG. 17, the flexible substrate may have interconnects that are configured to bend out-of-plane during stretching. Instead of the openings of FIG. 5, the flexible substrate may have slits that allow stretching of the substrate (as in FIGS. 18A-18D).

Next at step 104, the flexible substrate may be attached to a thermoplastic substrate. The flexible substrate may be attached to the thermoplastic substrate using optically clear adhesive. The stack-up of the flexible substrate with light-emitting diodes and the thermoformable substrate may be referred to as a thermoformable display or thermoformable display layers.

At step 106, the thermoformable display layers may be heated to soften the thermoplastic substrate. The thermoformable display layers may be heated such that the thermoplastic substrate exceeds its glass transition temperature and becomes pliable. The thermoformable display layers may be placed in a temperature-controlled chamber (e.g., an oven) during heating. Other heating techniques may be used if desired (e.g., a heat gun may be used to heat the display layers).

After the thermoplastic substrate is heated, the thermoformable display layers may be molded at step 108. A positive or negative mold may be used to bend the thermoformable display layers into a desired shape having desired curvature. For example, the thermoformable display layers may have curvature similar to as shown in region 12W-1 of FIG. 1. Alternatively, the thermoformable display layers may be molded to have a hemispherical upper surface.

At step 110, the thermoformable display layers may be cooled. Cooling the thermoformable display layers may cause the thermoplastic substrate to drop below its glass transition temperature and therefore harden. This secures the thermoplastic substrate and attached flexible substrate and light-emitting diodes in the desired shape having the desired curvature.

Finally, at step 112, the thermoformed display may be assembled into device 10. The thermoformed display may have an array of individually controllable light-emitting diodes. As discussed in connection with FIGS. 12 and 13, one or more additional thermoformed layers (e.g., a touch-sensitive layer, a lens layer, etc.) may be incorporated into the device. Additional covering layers such as a fabric layer may cover the thermoformed display.

The order of steps presented in FIG. 19 is merely illustrative. It should be understood that the order of some of these steps may be changed based on a device's particular design and various other variables that may affect manufacturing.

In the previous examples, a flexible substrate formed from flexible layers of polyimide with metal traces is used to support the light-emitting diodes. The flexible substrate is attached to a separate thermoplastic substrate in order to allow the flexible substrate to be stretched and secured in a desired shape. However, in an alternate embodiment the thermoplastic substrate may be omitted and the flexible substrate may itself be formed from a stretchable, thermoplastic material.

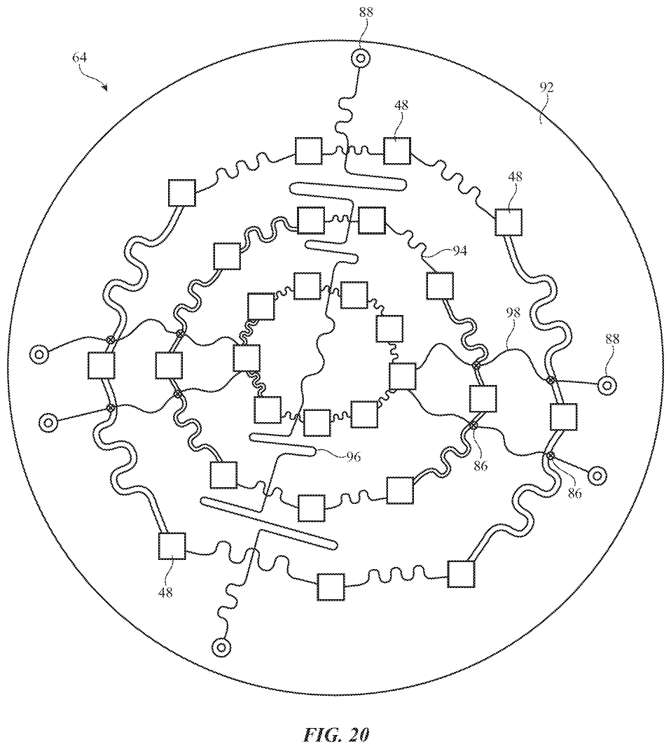

FIG. 20 is a top view of an illustrative thermoformable display formed from a stretchable polymer layer 92 (sometimes referred to as thermoplastic substrate, thermoplastic circuit substrate, stretchable circuit substrate, flexible substrate, thermoformable substrate, thermoplastic substrate, etc.). Stretchable polymer layer 92 may be formed form thermoplastic polyurethane (TPU) or another desired thermoplastic material. Traces may be printed onto the thermoplastic substrate to provide control and power signals to the light-emitting diodes.

Light-emitting diodes 48 are mounted on substrate 92. In the example of FIG. 20, the light-emitting diodes 48 are arranged in concentric circles. However, any other desired arrangement may be used for the light-emitting diodes. Traces such as serpentine traces 94, 96, and 98 may be connected to the light-emitting diodes and may provide signals to the light-emitting diodes. Traces 94, 96, and 98 may be serpentine to ensure the traces are not broken when the display layers are later stretched into a desired shape. Traces 96 and 98 may be coupled to external connection pads 88. The external connection pads 88 may be coupled to external control circuitry such as control circuitry 20 in FIG. 1. Traces 94 may be coupled between adjacent light-emitting diodes within the light-emitting diode array.

Each one of traces 94, 96, and 98 may be formed either within the substrate (e.g., embedded in the substrate) or on the substrate (e.g., on an outer surface of the substrate). Additionally, each trace may be formed from any desired material. The traces may be formed from copper, silver, or another desired material. In one illustrative example, traces 94 and 96 may be formed from copper (e.g., printed copper traces) and traces 98 may be formed from silver (e.g., silver paste). Vias such as vias 86 may be used to couple different traces to each other at various points.

Once substrate 92 and corresponding traces are formed, the substrate may be thermoformed. The thermoforming may be used to mold substrate 92 into a desired shape. Substrate 92 may then be cooled to secure the substrate in the desired shape. The thermoforming process may be similar to as previously discussed (e.g., in connection with FIG. 10), except for there is no thermoplastic substrate attached to the flexible substrate. Instead, the flexible substrate is itself thermoplastic. Consequently, flexible substrate 92 in FIG. 20 does not necessarily need to include openings or slits to promote stretching (although openings and/or slits may be included in substrate 92 if desired).

Traces may be formed on substrate 92 before or after the thermoforming process. In one illustrative example, copper traces may be used to form traces 94 and 96 before thermoforming. After thermoforming, silver paste may be used to form traces 98 on the surface of substrate 92. Traces 98 may be susceptible to cracking if stretched (e.g., during thermoforming). Forming traces 98 after thermoforming means that the traces will not need to be stretched and therefore the traces may be more robust than if formed before thermoforming.

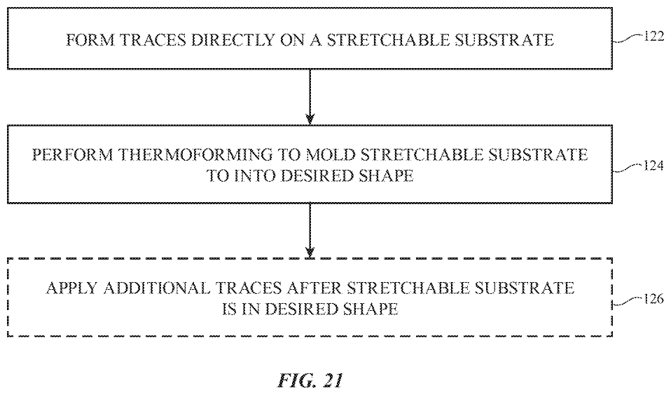

FIG. 21 is a flowchart showing illustrative method steps for forming a display using a stretchable substrate. First, at step 122, traces may be formed on a thermoplastic substrate such as TPU. Light-emitting diodes may be mounted on the thermoplastic substrate. The thermoplastic substrate does not need to have openings or slits to promote flexibility, though one or both may optionally be included. Traces formed on the substrate may have a serpentine shape to better tolerate stretching. The thermoplastic substrate with traces and light-emitting diodes may be referred to as a thermoformable display or thermoformable display layers.

Next at step 124, thermoforming may be performed to mold the thermoplastic substrate into a desired shape. The thermoformable display layers may be heated to soften the thermoplastic substrate 92. The thermoplastic substrate may be heated such that the thermoplastic substrate exceeds its glass transition temperature and becomes pliable. The thermoformable display layers may be placed in a temperature-controlled chamber (e.g., an oven) during heating. Other heating techniques may be used if desired (e.g., a heat gun may be used to heat the display layers).

After the thermoformable display layers are heated, the thermoformable display layers may be molded. A positive or negative mold may be used to bend the thermoplastic substrate into a desired shape having desired curvature. For example, the thermoplastic substrate 92 may have curvature similar to as shown in region 12W-1 of FIG. 1. Alternatively, the thermoplastic substrate may be molded to have a hemispherical upper surface. Once molded into a desired shape, the thermoplastic substrate 92 may be cooled, causing the thermoplastic substrate to drop below its glass transition temperature and therefore harden. This secures the thermoplastic substrate and attached light-emitting diodes in a desired shape having the desired curvature.

At step 126, additional traces (e.g., traces 98 in FIG. 20) may optionally be applied to the thermoplastic substrate after the thermoforming process is complete. This may allow traces that are potentially susceptible to breaking during the thermoforming process to be formed without reliability issues. The thermoformed display may be assembled into device 10, similar to as discussed in step 112 of FIG. 19.

The foregoing is merely illustrative and various modifications can be made to the described embodiments. The foregoing embodiments may be implemented individually or in any combination.

1. An electronic device, comprising:
a housing;
a speaker in the housing configured to emit sound;
a fabric layer having openings configured to allow the sound to pass; and
a display coupled to the housing, wherein the display is formed from a thermoplastic substrate layer, a flexible mesh substrate layer having a first surface that is attached to the thermoplastic substrate layer, and an array of light-emitting devices mounted to a second, opposing surface of the flexible mesh substrate layer, wherein the flexible mesh substrate layer is formed from a continuous grid of component support regions and interconnect regions that couple the component support regions, wherein the flexible mesh substrate layer has an array of substrate layer openings defined by the continuous grid, wherein each light-emitting device of the array of light-emitting devices is mounted on one of the component support regions of the flexible mesh substrate layer, wherein the fabric layer has a portion that covers the display, wherein the openings of the fabric layer are defined by fabric intersection points, and wherein each one of the light-emitting devices of the display is aligned orthogonally relative to a top surface of the display with a respective fabric intersection point.

2. The electronic device defined in claim 1 wherein the housing is cylindrical and is characterized by a longitudinal axis and wherein the array of light-emitting devices is configured to form a ring that extends around the longitudinal axis.

3. The electronic device defined in claim 2, wherein the electronic device has a cylindrical side surface that extends around the longitudinal axis and an upper surface and wherein the display defines a curved surface that extends between the upper surface and the cylindrical side surface.

4. (canceled)

5. The electronic device defined in claim 1, wherein the openings of the fabric layer comprise diamond-shaped openings each defined by four fabric intersection points.

6. (canceled)

7. The electronic device defined in claim 1, wherein the interconnect regions of the flexible mesh substrate layer comprise serpentine interconnect regions with at least one curved portion.

8. The electronic device defined in claim 1, further comprising:
a touch-sensitive layer formed over the display, wherein the display is nested within the touch-sensitive layer and the touch-sensitive layer conforms to the display.

9. The electronic device defined in claim 8, further comprising:
a lens layer formed over the touch-sensitive layer, wherein the touch-sensitive layer is nested within the lens layer and the lens layer conforms to the touch-sensitive layer.

10. The electronic device defined in claim 8, wherein the touch-sensitive layer is a thermoformed touch-sensitive layer with at least one thermoplastic substrate layer.

11. The electronic device defined in claim 1, wherein the display has regions with compound curvature.

12. The electronic device defined in claim 1, wherein the display has a hemispherical upper surface.

13. The electronic device defined in claim 1, wherein the display further comprises:
a first adhesive layer that attaches the flexible mesh substrate layer to the thermoplastic substrate layer;
an additional thermoplastic substrate layer, wherein the array of light-emitting devices is interposed between the thermoplastic substrate layer and the additional thermoplastic substrate layer; and
a second adhesive layer that attaches the light-emitting devices to the additional thermoplastic substrate layer.

14-17. (canceled)

18. A voice-controlled device, comprising:
a housing;
a speaker in the housing configured to emit sound;
a flexible polymer mesh layer having openings configured to form component support regions coupled by integral flexible polymer segments, wherein the flexible polymer mesh layer has first and second opposing surfaces;
light-emitting diodes mounted on the first surface of the flexible polymer mesh;
a fabric layer that covers the flexible polymer mesh layer, wherein the fabric layer has openings defined by fabric intersection points and wherein each one of the light-emitting diodes is aligned orthogonally relative to a top surface of the thermoplastic substrate with a respective fabric intersection point; and
a thermoplastic substrate, wherein the second surface of the flexible polymer mesh is attached to and conforms to the thermoplastic substrate.

19. The voice-controlled device defined in claim 18, wherein the thermoplastic substrate has a portion with compound curvature and wherein the flexible polymer mesh layer conforms to the portion with compound curvature.

20. A voice-controlled device, comprising:
a housing;
a speaker in the housing configured to emit sound;
a flexible polymer mesh having openings configured to form component support regions coupled by flexible polymer segments, wherein the flexible polymer mesh has first and second opposing sides;
electrical components mounted on the first side of the flexible polymer mesh;
a thermoplastic substrate, wherein the second side of the flexible polymer mesh is attached to and conforms to the thermoplastic substrate, wherein the thermoplastic substrate has a portion with compound curvature, wherein the flexible polymer mesh conforms to the portion with compound curvature, wherein the thermoplastic substrate is a first thermoplastic substrate, wherein the electrical components comprise an array of light-emitting diodes configured to form a display, wherein the housing is cylindrical and is characterized by a longitudinal axis, wherein the portion with compound curvature is formed between a cylindrical side surface of the voice-controlled device and an upper surface of the voice-controlled device, and wherein the display is configured to form a ring that extends around the longitudinal axis;
a first adhesive layer that is interposed between the first thermoplastic substrate and the flexible polymer mesh;
a second thermoplastic substrate, wherein the array of light-emitting diodes is interposed between the first and second thermoplastic substrates;
a second adhesive layer that is interposed between the array of light-emitting diodes and the second thermoplastic substrate;
a touch-sensitive layer that includes a third thermoplastic substrate, wherein the touch-sensitive layer conforms to the second thermoplastic substrate; and
a fabric layer having diamond-shaped openings, wherein at least a portion of the fabric layer overlaps the display and is configured to serve as a light diffuser for the display and wherein the portion of the fabric layer conforms to the touch-sensitive layer, wherein the diamond-shaped openings are defined by fabric intersection points and wherein each one of the light-emitting diodes is aligned orthogonally relative to a top surface of the display with a respective fabric intersection point.

21. The voice-controlled device defined in claim 18, wherein the flexible polymer mesh layer comprises metal traces that route signals between the light-emitting diodes.

22. The voice-controlled device defined in claim 21, wherein at least one of the metal traces extends from one of the component support regions onto one of the integral flexible polymer segments.

23. The voice-controlled device defined in claim 18, wherein the thermoplastic substrate has a portion with compound curvature, wherein the flexible polymer mesh layer conforms to the portion with compound curvature, wherein the light-emitting diodes comprise an array of light-emitting diodes configured to form a display, wherein the housing is cylindrical and is characterized by a longitudinal axis, wherein the portion with compound curvature is formed between a cylindrical side surface of the voice-controlled device and an upper surface of the voice-controlled device, and wherein the display is configured to form a ring that extends around the longitudinal axis.

24. The voice-controlled device defined in claim 18, wherein the thermoplastic substrate has a portion with compound curvature, wherein the flexible polymer mesh layer conforms to the portion with compound curvature, wherein the thermoplastic substrate is a first thermoplastic substrate, wherein the light-emitting diodes comprise an array of light-emitting diodes configured to form a display, wherein the housing is cylindrical and is characterized by a longitudinal axis, wherein the portion with compound curvature is formed between a cylindrical side surface of the voice-controlled device and an upper surface of the voice-controlled device, wherein the display is configured to form a ring that extends around the longitudinal axis, and wherein the voice-controlled device further comprises:
a touch-sensitive layer that includes a second thermoplastic substrate, wherein the touch-sensitive layer conforms to the first thermoplastic substrate.

25. (canceled)
